(19) United States
(12) Patent Application Publication
(10) Pub. No.: US 2020/0203581 A1
(43) Pub. Date: Jun. 25, 2020

(54) SINGLE CRYSTAL PHOSPHOR, PHOSPHOR-CONTAINING MEMBER AND LIGHT-EMITTING DEVICE

(71) Applicants: KOHA CO., LTD., Tokyo (JP); National Institute for Materials Science, Tsukuba-shi (JP)

(72) Inventors: Daisuke INOMATA, Tokyo (JP); Yusuke ARAI, Tokyo (JP); Hiroaki SANO, Tokyo (JP); Kazuo AOKI, Tokyo (JP); Kiyoshi SHIMAMURA, Tsukuba-shi (JP); Encarnacion Antonia GARCIA VILLORA, Tsukuba-shi (JP)

(73) Assignees: KOHA CO., LTD.; NATIONAL INSTITUTE FOR MATERIALS SCIENCE

(21) Appl. No.: 16/803,045

(22) Filed: Feb. 27, 2020

Related U.S. Application Data
(63) Continuation of application No. 14/774,583, filed on Sep. 10, 2015, now abandoned.

(30) Foreign Application Priority Data
Oct. 23, 2013 (JP) 2013-220681

(51) Int. Cl. H01L 33/50; C30B 15/00; H01L 33/48; C30B 33/00; C30B 15/36; C30B 15/30; C30B 15/14; C30B 15/10; C30B 29/28; C09K 11/77

(52) U.S. Cl. CPC H01L 33/502; H01L 2924/181; H01L 33/486; C30B 33/00; C30B 15/36; C30B 15/30; C30B 15/14; C30B 15/10; H01L 33/505; H01L 33/504; C30B 29/28; C09K 11/7774; H01L 2224/48091; H01L 2224/49107; H01L 2224/16245; C30B 15/00

(57) ABSTRACT

A phosphor-containing member includes a transparent member, and particles of a single crystal phosphor dispersed in the transparent member. The single crystal phosphor has a composition represented by a compositional formula (Y_{1-a-b}LuₐCe_{b})_{3+c}Al_{5-c}O₁₂ (where 0≤a≤0.9994, 0.0002≤b≤0.0067, −0.016≤c≤0.315), and Commission International de l'Eclairage (CIE) chromaticity coordinates x, y of an emission spectrum satisfy a relationship of −0.4377x+0.7384≤y≤−0.4377x+0.7504 when a peak wavelength of excitation light is 450 nm and temperature is 25° C.

The present application is a Continuation Application of U.S. patent application Ser. No. 14/774,583, filed on Sep. 10, 2015, which is based on International Application No. PCT/JP2014/078105, filed on Oct. 22, 2014, which is based on Japanese Patent Application No. 2013-220681, filed on Oct. 23, 2013, the entire contents of which are incorporated herein by reference.

### TECHNICAL FIELD

The invention relates to a single crystal phosphor, a phosphor-containing member and a light-emitting device.

### BACKGROUND ART

A light-emitting device is known in which a light-emitting element including an LED (Light Emitting Diode) to emit a bluish light is provided together with a phosphor to be excited by the light of the light-emitting element and to emit a yellowish light such that the mixture of these emission colors gives a white light (see e.g. PTL 1 and PTL 2).

The light-emitting device disclosed in PTL 1 uses a YAG: Ce polycrystalline phosphor ceramic sheet as the yellowish light-emitting phosphor.

The light-emitting device disclosed in PTL 2 uses a. powder of Cerium-activated Yttrium Aluminum Garnet (YAG: Ce)-based polycrystalline phosphor as the yellowish light-emitting phosphor.

### CITATION LIST

### Patent Literature

[PTL 1]

JP-A-2010-24278

[PTL2]

JP-B-3503139

### SUMMARY OF INVENTION

### Technical Problem

It is an object of the invention to provide a YAG-based single crystal phosphor to produce fluorescence in an unconventional color, as well as a phosphor-containing member and a light emitting device including the single crystal phosphor.

### Solution to Problem

According to one embodiment of the invention, a single crystal phosphor set forth in [1] to [3] below is provided so as to achieve the above object.

[1] A single crystal phosphor, comprising:
a composition represented by a compositional formula (Y_{1-a-b}LuₐCe_{b})_{3+c}Al_{5-c}O₁₂ (where 0≤a≤0,9994, 0.0002≤b≤0.0067, −0.016≤c≤0.315),
wherein Commission International de l'Eclairige (CIE) chromaticity coordinates x, y of an emission spectrum satisfy a relationship of −0.4377x+0.7384≤y≤−0.4585x+0.7504 when a peak wavelength of excitation light is 450 nm and temperature is 25° C.

[2] The single crystal phosphor according to [1], wherein a value of “a” in the compositional formula of the single crystal phosphor is in a range of 0.0222≤a≤0.9994.

[3] The single crystal phosphor according to [1], wherein the value of “a” in the compositional formula of the single crystal phosphor is 0.

According to another embodiment of the invention, a light emitting device set forth in [4] to [7] below is provided so as to achieve the above object.

[4] A light-emitting device, comprising:
a light-emitting element to emit a bluish light; and
a yellowish phosphor to absorb the light emitted by the light-emitting element and produce a yellowish fluorescence,
wherein the yellowish phosphor comprises the single crystal phosphor according to any one of [1] to [3].

[5] The light-emitting device according to [4], further comprising a reddish phosphor to absorb the light emitted by the light-emitting element and produce a reddish fluorescence.

[6] The light-emitting device according to [4], wherein the single crystal phosphor is disposed off from the light-emitting element.

[7] The light-emitting device according to [4], wherein the single crystal phosphor is plate-shaped.

According to another embodiment of the invention, a phosphor-containing member set forth in [8] and [9] below is provided so as to achieve the above object.

[8] A phosphor-containing member, comprising:
a transparent member; and
particles of phosphor dispersed in the transparent member,
wherein the particles of phosphor comprise the single crystal phosphor according to any one of [1] to [3].

[9] The phosphor-containing member according to [8], wherein the transparent member comprises a transparent inorganic material.

According to another embodiment of the invention, a light emitting device set forth in [10] below is provided so as to achieve the above object.

[10] A light-emitting device, comprising:
a light-emitting element to emit a bluish light; and
the phosphor-containing member according to [8].

### Advantageous Effects of the Invention

According to one embodiment of the invention, a YAG-based single crystal phosphor to produce fluorescence in an unconventional color can be provided as well as a phosphor-containing member and a light emitting device including the single crystal phosphor.

### BRIEF DESCRIPTION OF DRAWINGS

FIG. 1 is a graph showing composition distribution in a single crystal phosphor in a first embodiment used for evaluation.

FIG. 2 is a graph showing CIE (x, y) chromaticity distribution of the single crystal phosphor in the first embodiment used for evaluation.

FIG. 3A is a vertical cross-sectional view showing a light-emitting device in a second embodiment.

FIG. 3B is an enlarged view showing a light-emitting element and the periphery thereof in the light-emitting device.

FIG. 4 is a chromaticity diagram which plots the CIE chromaticity of light (fluorescence) emitted from the single crystal phosphor alone and the CIE chromaticity of a mixture light of light emitted from the light-emitting element and light emitted from the single crystal phosphor.

FIG. 5 is a chromaticity diagram which plots the CIE chromaticity of a mixture light yielded by a combination of the light-emitting element, the single crystal phosphor and a reddish phosphor.

FIG. 6 shows emission spectra of the light-emitting element, the single crystal phosphor and the reddish phosphor which were used for simulation (these spectra are referred to as “fundamental spectra”).

FIG. 7A is a vertical cross-sectional view showing a light-emitting device in a third embodiment.

FIG. 7B is an enlarged view showing a light-emitting element and the periphery thereof in the light-emitting device.

FIG. 7C is a top view showing the light-emitting element.

FIG. 8 is a vertical cross-sectional view showing a light-emitting device in a fourth embodiment.

FIG. 9 is a vertical cross-sectional view showing a light-emitting device in a fifth embodiment.

FIG. 10 is a vertical cross-sectional view showing a light-emitting device in a sixth embodiment.

### DESCRIPTION OF EMBODIMENTS

### First Embodiment

### Single Crystal Phosphor

A single crystal phosphor in the first embodiment is a Ce-doped YAG-activated single crystal phosphor and has a composition represented by (Y_{1-a-b}LuₐCe_{b})3+_{c}Al5−_{c}O₁₂ (where 0≤a≤0.9994, 0.0002≤b≤0,0067, −0.016≤c≤0.315). Here, Ce is substituted in the Y site and functions as an activator (becomes the light emission center). On the other hand, Lu is substituted in the Y site hut does not function as an activator.

In the composition of the phosphor, some atoms may be in different positions in the crystal structure. In addition, although the composition ratio of O in the compositional formula is 12, the above-mentioned composition also includes compositions with an O composition. ratio slightly different from 12 due to presence of oxygen which is inevitably mixed or deficient. In addition, the value of c in the compositional formula is a value inevitably variable when manufacturing the single crystal phosphor, but variation within a range of about −0.016≤c≤.0.315 have little effect on physical properties of the single crystal phosphor.

It is possible to obtain the single crystal phosphor in the first embodiment by, e.g., a liquid phase growth method such as CZ method (Czochralski method), EGF method (Edge Defined Film Fed Growth Method), Bridgman method, FZ method (Floating Zone method) or Verneuil method, etc. Ingots of single crystal phosphors obtained by such liquid phase growth methods are cut into flat plates or processed into powder, which are then available for manufacturing light-emitting devices described later.

The value of “b” indicating the Ce concentration in the above-mentioned compositional formula is in a range of 0.0002≤a≤0.0067 because when the value of b is smaller than 0.0002, too low Ce concentration causes a decrease in absorption of excitation light and a resulting problem of an excessive decrease in external quantum efficiency and, when larger than 0.0067, cracks or voids, etc., are highly likely to be generated during growth of an ingot of single crystal phosphor and thus cause a decrease in crystal quality.

### Manufacture of Single Crystal Phosphor

A manufacturing method using the Czochralski process will be described below as an example of the method of manufacturing the single crystal phosphor in the present embodiment.

Firstly, Y₂O₃, Lu₂O₃, CeO₂ and Al₂O₃ each in the form of powder having a high purity (not less than 99.99%) are prepared as starting materials and are thy-blended, thereby obtaining a mixture powder. In this regard, powder raw-materials of Y Lu, Ce and Al are not limited to the above mentioned materials. In addition, when manufacturing a single crystal phosphor not containing Lu, the powder raw-material thereof is not used.

Next, the obtained mixture powder is put in a crucible made of indium and the crucible is then placed in a ceramic cylindrical container. Then, a high frequency energy of 30 kW is supplied to the crucible by a high-frequency coil wound around the cylindrical container to generate induced current, thereby heating the crucible. The mixture powder is melted and a melt thereof is thereby obtained.

Next, a seed crystal which is a YAG single crystal is prepared and, after bringing a tip thereof into contact with the melt, is pulled upward at a pulling speed of not more than 1 mm/h and rotated simultaneously at a rotation speed of 10 rpm at a temperature of not less than 1960° C., thereby growing a single crystal phosphor ingot oriented to the <11122 direction. The single crystal phosphor ingot is grown in a nitrogen atmosphere at atmospheric pressure in a state that nitrogen is being supplied at a flow rate of 2 L/min into the cylindrical container.

A single crystal phosphor ingot having, e.g., a diameter of about 2.5 cm and a length of about 5 cm is thereby obtained. By cutting the obtained single crystal phosphor ingot into a desired size, it is possible to obtain, e.g., a plate-shaped single crystal phosphor to be used in a light-emitting device. Or, by grinding the single crystal phosphor ingot, it is possible to obtain particles of single crystal phosphor.

### Evaluation of Single Crystal Phosphor

Plural single crystal phosphors in the first embodiment which have different compositions were made. Then, analysis of the compositions and evaluations for CIE chromaticity and internal quantum efficiency were performed.

Composition analysis was performed using high-frequency inductively-coupled plasma (ICP) emission spectrometry. For analyzing the single crystal phosphors having an extremely low Ce concentration, ICP mass spectrometry (ICP-MS) was used in combination.

For evaluating CIE chromaticity coordinates, CIE 1931 color-matching functions were used to obtain the CIE chromaticity coordinates of the emission spectrum of the single crystal phosphors when the peak wavelength of the excitation light is 450 mm.

The internal quantum efficiency was evaluated using a quantum efficiency measurement system having an integrating hemisphere unit. The following is a specific method of measuring the internal quantum efficiency of the single crystal phosphor.

Firstly, excitation light is irradiated onto barium sulfate powder provided as a standard sample and placed in the integrating hemisphere unit, and the excitation light spectrum is measured, Next, excitation light is irradiated onto the single crystal phosphor placed on the barium sulfate in the integrating hemisphere unit, and the excitation light reflection spectrum and the fluorescence spectrum are measured. Next, in the integrating hemisphere unit, the diffusely-reflected excitation light is irradiated onto the single crystal phosphor placed on the barium sulfate and the re-excitation fluorescence spectrum is measured.

Then, a difference between the number of photons obtained from the fluorescence spectrum and the number of photons obtained from the re-excitation fluorescence spectrum is divided ^{by,} a difference between the number of photons obtained from the excitation light spectrum and the number of photons obtained from the excitation light reflection spectrum. The internal quantum efficiency is thereby obtained.

Table 1 below shows the results of evaluating the wavelength of fluorescence and the CIE chromaticity. In Tablet the samples No.1 to No.33 are samples of the single crystal phosphors in the present embodiment and the samples No.34 to No.36 are samples of Ce-activated YAG based polycrystalline phosphor powder as Comparative Examples. Table 1 shows the values of a, b and c in the compositional formula of the single crystal phosphor in the present embodiment, the peak wavelengths λp (nm) of fluorescence when the peak wavelength of the excitation light is 440 nm, 450 nm and 460 nm, and the CIE chromaticity coordinates (x, y) when the peak wavelength of the excitation light is 440 nm, 450 nm and 460 nm.

TABLE 1

| | | | | λp | λp | λp | | | | | | |
|---|---|---|---|---|---|---|---|---|---|---|---|---|
| | | | | [nm] | [nm] | [nm] | CIE chromaticity | | CIE chromaticity | | CIE chromaticity | |
| Sample | | | | at 440 | at 450 | at 460 | at 440 nm | | at 450 nm | | at 460 nm | |
| No. | a | b | c | nm | nm | nm | x-coordinate | y-coordinate | x-coordinate | y-coordinate | x-coordinate | y-coordinate |
| 1 | 0.2909 | 0.0017 | 0.022 | 538 | 536 | 538 | 0.409 | 0.568 | 0.411 | 0.567 | 0.412 | 0.566 |
| 2 | 0.9994 | 0.0006 | 0.023 | 514 | 515 | 514 | 0.329 | 0.600 | 0.329 | 0.600 | 0.330 | 0.599 |
| 3 | 0 | 0.0013 | 0.000 | 533 | 539 | 534 | 0.415 | 0.562 | 0.415 | 0.562 | 0.415 | 0.562 |
| 4 | 0 | 0.0047 | 0.005 | 540 | 540 | 539 | 0.421 | 0.559 | 0.421 | 0.559 | 0.422 | 0.559 |
| 5 | 0 | 0.0067 | −0.010 | 545 | 546 | 545 | 0.434 | 0.550 | 0.434 | 0.551 | 0.434 | 0.551 |
| 6 | 0 | 0.0014 | 0.175 | 540 | 541 | 542 | 0.424 | 0.558 | 0.425 | 0.557 | 0.424 | 0.557 |
| 7 | 0 | 0.0014 | 0.228 | 541 | 543 | 542 | 0.424 | 0.558 | 0.424 | 0.558 | 0.424 | 0.557 |
| 8 | 0 | 0.0014 | 0.167 | 540 | 543 | 541 | 0.426 | 0.557 | 0.426 | 0.557 | 0.425 | 0.556 |
| 9 | 0 | 0.0002 | 0.137 | 531 | 531 | 531 | 0.405 | 0.566 | 0.405 | 0.564 | 0.403 | 0.559 |
| 10 | 0 | 0.0002 | 0.190 | 531 | 530 | 536 | 0.405 | 0.564 | 0.405 | 0.564 | 0.403 | 0.559 |
| 11 | 0 | 0.0005 | 0.054 | 530 | 533 | 529 | 0.412 | 0.563 | 0.412 | 0.563 | 0.411 | 0.561 |
| 12 | 0 | 0.0010 | 0.128 | 540 | 537 | 538 | 0.420 | 0.560 | 0.420 | 0.560 | 0.419 | 0.559 |
| 13 | 0.0222 | 0.0013 | 0.021 | 530 | 531 | 531 | 0.407 | 0.567 | 0.408 | 0.566 | 0.408 | 0.564 |
| 14 | 0.0905 | 0.0013 | −0.016 | 533 | 536 | 537 | 0.415 | 0.562 | 0.415 | 0.562 | 0.415 | 0.561 |
| 15 | 0.1133 | 0.0013 | 0.002 | 533 | 531 | 531 | 0.405 | 0.567 | 0.406 | 0.567 | 0.406 | 0.564 |
| 16 | 0.1436 | 0.0014 | −0.006 | 530 | 530 | 531 | 0.406 | 0.568 | 0.407 | 0.567 | 0.408 | 0.565 |
| 17 | 0.2735 | 0.0006 | 0.036 | 529 | 528 | 528 | 0.395 | 0.574 | 0.397 | 0.572 | 0.399 | 0.571 |
| 18 | 0.5301 | 0.0009 | 0.047 | 528 | 528 | 530 | 0.381 | 0.582 | 0.384 | 0.581 | 0.386 | 0.579 |
| 19 | 0.2324 | 0.0002 | 0.140 | 525 | 525 | 528 | 0.388 | 0.572 | 0.390 | 0.571 | 0.390 | 0.565 |
| 20 | 0.2239 | 0.0002 | 0.170 | 524 | 529 | 525 | 0.387 | 0.570 | 0.389 | 0.569 | 0.390 | 0.566 |
| 21 | 0.2183 | 0.0002 | 0.161 | 528 | 526 | 527 | 0.387 | 0.571 | 0.389 | 0.569 | 0.391 | 0.566 |
| 22 | 0.1955 | 0.0003 | 0.315 | 528 | 531 | 530 | 0.394 | 0.572 | 0.396 | 0.571 | 0.396 | 0.567 |
| 23 | 0.1892 | 0.0008 | 0.112 | 531 | 532 | 533 | 0.405 | 0.569 | 0.406 | 0.568 | 0.407 | 0.566 |
| 24 | 0.2298 | 0.0004 | 0.158 | 530 | 529 | 533 | 0.399 | 0.572 | 0.401 | 0.571 | 0.402 | 0.570 |
| 25 | 0.2099 | 0.0006 | 0.216 | 534 | 531 | 531 | 0.405 | 0.570 | 0.406 | 0.569 | 0.407 | 0.568 |
| 26 | 0.1886 | 0.0011 | 0.251 | 537 | 536 | 538 | 0.412 | 0.566 | 0.413 | 0.565 | 0.414 | 0.565 |
| 27 | 0.2932 | 0.0006 | 0.152 | 529 | 531 | 532 | 0.400 | 0.573 | 0.402 | 0.571 | 0.403 | 0.570 |
| 28 | 0.2821 | 0.0009 | 0.158 | 533 | 533 | 534 | 0.404 | 0.571 | 0.406 | 0.570 | 0.407 | 0.569 |
| 29 | 0.2597 | 0.0014 | 0.168 | 543 | 539 | 539 | 0.412 | 0.567 | 0.413 | 0.566 | 0.415 | 0.565 |
| 30 | 0.3528 | 0.0009 | 0.177 | 533 | 531 | 531 | 0.399 | 0.574 | 0.400 | 0.573 | 0.402 | 0.571 |
| 31 | 0.3357 | 0.0012 | 0.145 | 533 | 533 | 535 | 0.404 | 0.572 | 0.405 | 0.571 | 0.407 | 0.569 |
| 32 | 0.3109 | 0.0021 | 0.130 | 543 | 543 | 543 | 0.415 | 0.565 | 0.417 | 0.564 | 0.418 | 0.563 |
| 33 | 0.3357 | 0.0012 | 0.145 | 527 | 527 | 529 | 0.385 | 0.573 | 0.387 | 0.571 | 0.390 | 0.570 |
| 34 | | | | 522 | 520 | 524 | 0.344 | 0.585 | 0.344 | 0.585 | 0.347 | 0.584 |
| 35 | | | | 546 | 545 | 547 | 0.403 | 0.560 | 0.404 | 0.559 | 0.407 | 0.558 |
| 36 | | | | 543 | 543 | 544 | 0.419 | 0.555 | 0.418 | 0.557 | 0.419 | 0.556 |

As shown in Table 1, the values of a, b and c the compositional formula (Y_{1-a-b}LuₐCe_{b})3+_{c}Al5−_{c}O₁₂ expressing the single crystal phosphors used for the evaluation are respectively in the ranges of 0≤a≤0.9994, 0.0002≤b≤0,0067, −0.016≤c≤0.315.

The value of a in the compositional formula of the single crystal phosphors containing Lu is in a range of 0.0222≤a≤0.9994, and the value of a in the compositional formula of the single crystal phosphors not containing Lu is a=0.

The single crystal phosphors containing Lu, which produce fluorescence of a color closer to green than that of the single crystal phosphors not containing Lu, can create white light having high color rendering properties when used with a blue light source in combination with a reddish phosphor. On the other hand, the single crystal phosphors not containing Lu can create white light with a high color temperature when used with a blue light source without a combination with a reddish phosphor.

The single crystal phosphors containing Lu generally have better temperature characteristics than the single crystal phosphors not containing Lu. However, since Lu is expensive, the manufacturing cost increases when adding Lu to the single crystal phosphor.

In addition, based on. Table 1, when the values of a and h in the compositional formula of the single crystal phosphors used for the evaluation are respectively in the ranges of 0≤a≤0.9994 and 0.0002≤b≤0.0067, the x and y values of the CIE chromaticity coordinates for fluorescence are respectively in the ranges of 0.329≤x≤0.434 and 0.551≤y≤0.600 when the peak wavelength of the excitation light is 450 nm.

FIG. 1 is a graph showing composition distribution in the single crystal phosphor in the first embodiment used for the evaluation. In FIG. 1, the horizontal axis indicates the value of a (Lu concentration) in the compositional formula of the single crystal phosphor and the vertical axis indicates the value of b (Ce concentration) in the compositional formula.

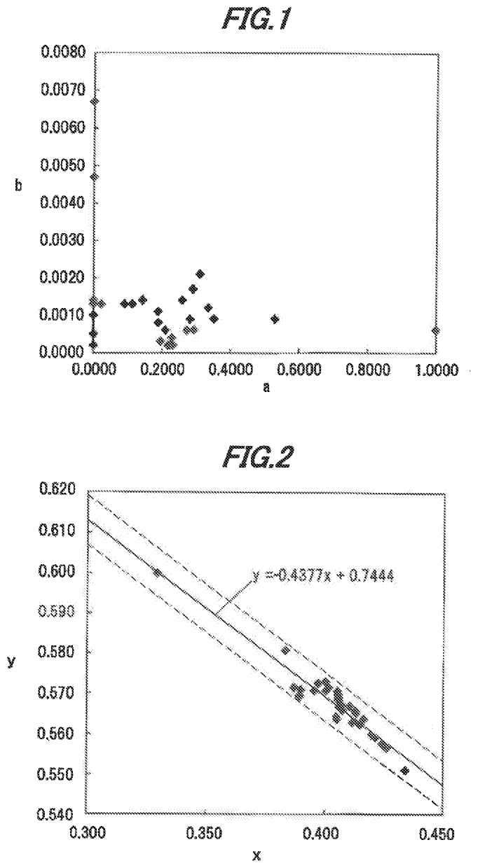

FIG. 2 is a graph showing CIE (xy) chromaticity distribution of the single crystal phosphor in the first embodiment used for the evaluation. In FIG. 2 which shows the CIE chromaticity when the peak wavelength of the excitation light is 450 nm, the horizontal axis indicates the x-coordinate and the vertical axis indicates the y-coordinate,

The straight line y=0.4377x+0.7444 in FIG. 2 is an approximate straight line of the CIE chromaticity coordinates at the peak wavelength of 450 nm and is derived by the least-squares method. Then, a dotted line above the approximate straight line is a line represented by y=−0.4585x+0.7504 and a dotted line below is a line represented by y=−0.4377x+0.7384.

As shown in FIG. 2, in the single crystal phosphor which has a composition represented by a compositional formula (Y_{1-a-b}LuₐCe_{b})3+_{c}Al5−_{c}O₁₂(where 0≤a≤0.9994, 0.0002≤b≤0.0067, '0.016≤c≤0.315), the CIE xy chromaticity coordinates of emission spectrum satisfy the relation −0.4377x+0.7384≤y≤−0.4585x+0.7504 when the peak wavelength of the excitation light is 450 nm and the temperature is 25° C.

Table 2 below shows the results of evaluating the internal quantum efficiency. Table 2 shows the values of a, b and c in the compositional formula of the single crystal phosphors in the present embodiment and internal quantum efficiency (ηᵢₙₜ) at 25° C. when the peak wavelength of the excitation light is 440 nm, 450 nm and 460 nm.

TABLE 2

| Sample | | | | Internal quantum efficiency (ηᵢₙₜ) | | |
|---|---|---|---|---|---|---|
| No. | a | b | c | 440 nm | 450 nm | 460 nm |
| 1 | 0.2909 | 0.0017 | 0.022 | 0.98 | 0.98 | 0.97 |
| 2 | 0.9994 | 0.0006 | 0.023 | 1.00 | 0.99 | 0.97 |
| 3 | 0 | 0.0013 | 0.000 | 1.00 | 0.99 | 0.96 |
| 4 | 0 | 0.0047 | 0.005 | 0.99 | 0.98 | 0.98 |
| 5 | 0 | 0.0067 | −0.010 | 1.00 | 1.00 | 1.00 |
| 6 | 0 | 0.0014 | 0.175 | 0.99 | 0.98 | 0.99 |
| 7 | 0 | 0.0014 | 0.228 | 1.00 | 0.98 | 0.99 |
| 8 | 0 | 0.0014 | 0.167 | 0.99 | 0.97 | 0.98 |
| 9 | 0 | 0.0002 | 0.137 | 0.95 | 0.96 | 0.95 |
| 10 | 0 | 0.0002 | 0.190 | 0.96 | 1.00 | 0.96 |
| 11 | 0 | 0.0005 | 0.054 | 0.95 | 0.99 | 0.94 |
| 12 | 0 | 0.0010 | 0.128 | 0.97 | 0.96 | 0.96 |
| 13 | 0.0022 | 0.0013 | 0.021 | 1.00 | 0.99 | 0.96 |
| 14 | 0.0905 | 0.0013 | −0.016 | 1.00 | 0.96 | 0.96 |
| 15 | 0.1133 | 0.0013 | 0.002 | 0.98 | 0.97 | 0.95 |
| 16 | 0.1434 | 0.0014 | −0.006 | 0.99 | 0.96 | 0.98 |
| 17 | 0.2735 | 0.0006 | 0.036 | 0.94 | 0.98 | 0.96 |
| 18 | 0.5301 | 0.0009 | 0.047 | 0.97 | 0.96 | 0.96 |
| 19 | 0.2324 | 0.0002 | 0.140 | 0.91 | 0.91 | 0.95 |
| 20 | 0.2239 | 0.0002 | 0.170 | 0.93 | 0.98 | 0.95 |
| 21 | 0.2183 | 0.0002 | 0.161 | 0.99 | 0.96 | 0.97 |
| 22 | 0.1955 | 0.0003 | 0.315 | 0.93 | 0.94 | 0.94 |
| 23 | 0.1892 | 0.0008 | 0.112 | 0.96 | 0.96 | 0.96 |
| 24 | 0.2298 | 0.0004 | 0.158 | 0.93 | 0.96 | 0.96 |
| 25 | 0.2099 | 0.0006 | 0.216 | 0.98 | 0.94 | 0.96 |
| 26 | 0.1886 | 0.0011 | 0.251 | 0.98 | 1.00 | 0.97 |
| 27 | 0.2932 | 0.0006 | 0.152 | 0.96 | 0.95 | 0.96 |
| 28 | 0.2821 | 0.0009 | 0.158 | 0.98 | 0.99 | 0.99 |
| 29 | 0.2597 | 0.0014 | 0.168 | 0.99 | 0.99 | 0.99 |
| 30 | 0.3528 | 0.0009 | 0.177 | 0.98 | 0.95 | 0.96 |
| 31 | 0.3357 | 0.0012 | 0.145 | 0.99 | 0.98 | 0.95 |
| 32 | 0.3109 | 0.0021 | 0.130 | 0.98 | 0.98 | 0.96 |
| 33 | 0.3357 | 0.0012 | 0.145 | 0.94 | 0.94 | 0.94 |

Based on Table 2, the single crystal phosphors in the present embodiment have high internal quantum efficiency. All of the evaluated single crystal phosphor samples have an internal quantum efficiency of, e.g., not less than 0.91 when the temperature is 25° C. and the peak wavelength of the excitation light is 450 nm.

The shapes of the evaluated single crystal phosphor samples are as follows: the samples No.15 to No.19 were 0.3 mm-thick circular flat plates having a diameter of 10 mm; the sample No.33 was powder; and the other samples were 0.3 mm-thick square flat plates of 10 mm in each side. In addition, all samples except the powder sample had mirror-polished surfaces on both sides.

The peak wavelength λp (nm) of fluorescence, the CIE chromaticity coordinates (x, y) and the measured values of internal quantum efficiency are hardly affected by the shapes of the samples.

### Comparison with Polycrystalline Phosphor

A relation of the Ce concentration with emission color is largely different between the Ce-activated YAG-based single crystal phosphor and the YAG-based polycrystalline phosphor powder. It is set forth in, e.g., PTL 1 (JP-A-2010-24278) that polycrystalline phosphor powder having a composition represented by a compositional formula (Y_{1-z}Ce_{z})₃Al₅O₁₂ emits light with a specific chromaticity of (0.41, 0.56) in a Ce concentration range of 0.003≤z≤0.2. On the other hand, the single crystal phosphor in the present embodiment has a chromaticity varying depending on the Ce concentration and its composition is, e.g., (Y_{a-z}Ce_{z})₃Al₅O₁₂ (z=0.0005) to emit light with the same chromaticity (0.41, 0.56) as the polycrystalline phosphor powder of PTL 1.

Meanwhile, it is set forth in PTL 2 (JP-B-3503139) that polycrystalline phosphor powder having a composition represented by a compositional formula (Y_{a-a-b}LuₐCe_{b})₃Al₅O₁₂ emits light with a chromaticity of (0.339, 0.579) when a=0.99 and b=0.01 and emits light with a chromaticity of (0.377, 0.570) when a=0.495 and b=0.01. The concentration of Ce contained in this polycrystalline phosphor powder is also several orders of Magnitude higher than the concentration ref Ce contained in the single crystal phosphor in the present embodiment.

As such, the concentration of Ce added to the single crystal phosphor to emit light with a desired color is extremely lower than the polycrystalline phosphor and it is possible to reduce the amount of expensive Ce to be used.

### Second embodiment

The second embodiment is a light-emitting device having the single crystal phosphor of the first embodiment.

### Configuration of Light-Emitting Device

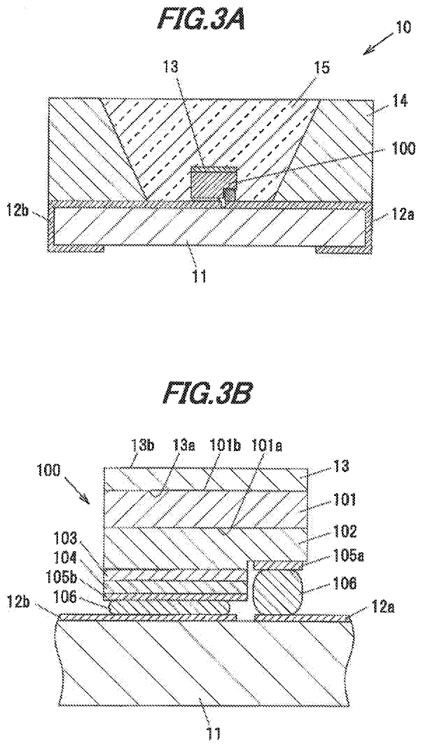

FIG. 3A is a vertical cross-sectional view showing a light-emitting device, 10 in the second embodiment. FIG. 3B is an enlarged view showing a light-emitting element 100 and the periphery thereof in the light-emitting device 10.

The light-emitting device 10 has a substrate 11 having wirings 12a and 12b on the surface thereof, the light-emitting element 100 mounted on the substrate 11, a single crystal phosphor 13 provided on the light-emitting element 100, an annular sidewall 14 surrounding the light-emitting element 100, and a sealing material 15 for sealing the light-emitting element 100 and the single crystal phosphor 13.

The substrate 11 is formed of, e.g., ceramics such as Al₂O₃, The wirings 12a and 12b are pattern-formed on the surface of the substrate 11. The wirings 12a and 12b are formed of, e.g., a metal such as tungsten.

The light-emitting element 100 is a flip-chip type LED chip and emits bluish light. The peak emission wavelength of the light-emitting element 100 s preferably in a range of 430 to 480 nm from the viewpoint of internal quantum efficiency of the light-emitting element 100, and is more preferably in a range of 440 to 470 nm from the viewpoint of internal quantum efficiency of the single crystal phosphor 13.

In the light-emitting element 100, an n-type semiconductor layer 102 formed of, e.g., GaN doped with an n-type impurity, a light-emitting layer 103 and a p-type semiconductor layer 104 formed of, e.g., GaN doped with a p-type impurity are laminated in this order on a first main surface 101a of an element substrate 101 formed of sapphire, etc. An n-side electrode 105a is formed on the exposed portion of the n-type semiconductor layer 102 and a p-side electrode 105b is formed on the surface of the p-type semiconductor layer 104.

Carriers are injected from the n-type semiconductor layer 102 and the p-type semiconductor layer 104 into the light-emitting layer 103 which thereby emits bluish light. The light emitted from the light-emitting layer 103 is transmitted through the n-type semiconductor layer 102 and the element substrate 101 and exits from a second main surface 101b of the element substrate 101. That is, the second main surface 101b of the element substrate 101 is a light-emitting surface of the light-emitting element 100.

The single crystal phosphor 13 is arranged on the second main surface 101b of the element substrate 101 so as to cover the entire second main surface 101b.

The single crystal phosphor 13 is a plate-shaped single crystal phosphor formed of the single crystal phosphor in the first embodiment. The single crystal phosphor 13 is formed of one single crystal and thus does not include grain boundaries. The single crystal phosphor 13 has an area equal to or greater than the second main surface 101b. The single crystal phosphor 13 absorbs light emitted by the light-emitting element 100 and produces yellowish fluorescence.

The single crystal phosphor 13 is placed directly on the second main surface 101b of the element substrate 101 without interposition of any members such that a first surface 13a, which is a surface of the single crystal phosphor 13 on the element substrate 101 side, is in contact with the second main surface 101b of the element substrate 101. The single crystal phosphor 13 and the element substrate 101 are bonded by, e.g., an intermolecular force.

The n-side electrode 105a and the p-side electrode 105b of the light-emitting element 100 are electrically connected respectively to the wirings 12a and 12b via conductive bumps 106.

The sidewall 14 is formed of a resin such as silicone-based resin or epoxy-based resin and may contain light reflective particles of titanium dioxide, etc.

The sealing material 15 is formed of, e.g., a translucent resin such as silicone-based resin or epoxy-based resin. The sealing material 15 may contain particles of reddish phosphor which absorbs the light emitted from the light-emitting element 100 and emits reddish fluorescence. From the viewpoint of brightness and color rendering properties, the peak emission wavelength of the reddish phosphor is preferably in a range of 600 to 660 nm, more preferably, in a range of 635 to 655 nm, Its wavelength when too small is close to the emission wavelength of the single crystal phosphor 13 and causes a decrease in color rendering properties. On the other hand, too large wavelength increases the influence on a decrease in luminous sensitivity.

### Operation of Light-Emitting Device

When power is distributed to the light-emitting element .100, electrons are injected into the light-emitting layer 103 through the wiring 12a, the n-side electrode 105a and the n-type semiconductor layer 102 while holes are injected into the light-emitting layer 103 through the wiring 12b, the p-side electrode 105b and the p-type semiconductor layer 104, resulting in that the light-emitting layer 103 emits light.

Bluish light emitted from the light-emitting layer 103 is transmitted through the n-type semiconductor layer 102 and the element substrate 101, exits from the second main surface 101b of the element substrate 101 and is incident on the first surface 13a of the single crystal phosphor 13.

The single crystal phosphor 13 absorbs a portion of bluish light emitted from the light-emitting element 100 and produces yellowish fluorescence.

A portion of the bluish light emitted from the light-emitting element 100 and travelling toward the single crystal phosphor 13 is absorbed by the single crystal phosphor 13, is wavelength-converted and exits as yellowish light from a second surface 13b of the single crystal phosphor 13. Meanwhile, another portion the bluish light emitted from the light-emitting element 100 and travelling toward the single crystal phosphor 13 exits from the second surface 13b without being absorbed by the single crystal phosphor 13. Since blue and yellow are complementary colors, the light-emitting device 10 emits white light as a mixture of blue light and yellow light.

Meanwhile, in case that the sealing material 15 contains a reddish phosphor, the reddish phosphor absorbs a portion of the bluish light emitted from the light-emitting element 100 and produces reddish fluorescence. In this case, the light-emitting device 10 emits white light as a mixture of blue light, yellow light and red light, Mixing the red light improves color rendering properties of white light.

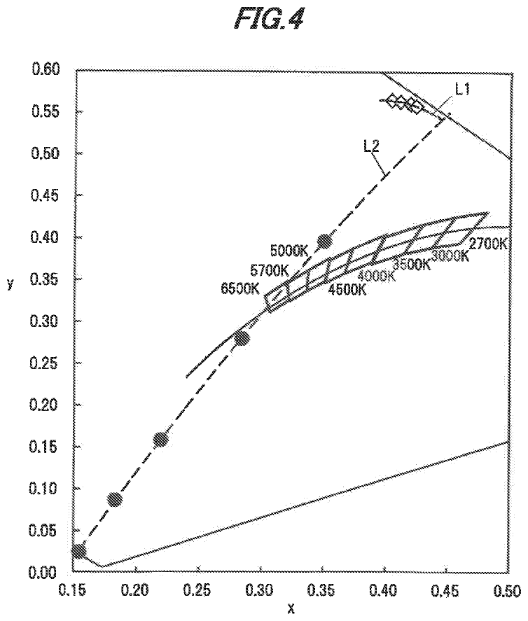

FIG. 4 is a chromaticity diagram which plots the CIE chromaticity of light (fluorescence) emitted from the single crystal phosphor 13 alone and the CIE chromaticity of a mixture light of light emitted from the light-emitting element 100 and light emitted from the single crystal phosphor 13. Eight quadrilateral boxes arranged in a row in FIG. 4 are chromaticity ranges at color temperatures of 2700 to 6500K defined by the chromaticity standard (ANSI C78.377).

A curved line L1 in FIG. 4 represents a relation between the Ce concentration and emission chromaticity, of the single crystal phosphor 13, Open diamond markers “⋄” on the curved line L1 are the actual measured values of emission chromaticity of the single crystal phosphor 13 when the value of b (Ce concentration) in the compositional formula of the single crystal phosphor 13 is 0.0002, 0.0005, 0.0010 and 0.0014 in order from left to right.

A curved line L2 in FIG. 4 represents a relation between the Ce concentration in the single crystal phosphor 13 and chromaticity of a mixture light yielded by a combination of the light-emitting element 100 and the single crystal phosphor 13. Filled circle markers “ [symbol] ” on the curved line L2 are the actual measured values of the chromaticity of the mixture light yielded by a combination of the light-emitting element 1110 and the single crystal phosphor 13 when the value of b in the compositional formula of the single crystal phosphor 13 is 0.0002, 0.0005, 0.0010 and 0.0014 in order from bottom to top.

These actual measured values were obtained by measuring the fluorescence spectrum of the single crystal phosphor 13 and the synthetic spectrum of light from the light-emitting element 100 with fluorescence from the single crystal phosphor 13 when the value of a is fixed to 0 and the value of b is varied in the compositional formula (Y_{1-a-b}LuₐCe_{b})_{3+c}Al_{5-c}O₁₂ of the single crystal phosphor 13.

The emission wavelength of the light-emitting element 100 used for this measurement is 450 nm. The single crystal phosphor 13 is a plate-shaped single crystal phosphor having a thickness of 0.3 mm.

As indicated by the curved lines L1 and L2, due to Ce which functions as an activator for the single crystal phosphor 13, the chromaticity of the mixture light yielded by a combination of the light-emitting element 100 and the single crystal phosphor 13 becomes closer to the chromaticity of fluorescence from the single crystal phosphor 13 alone as the Ce concentration in the single crystal phosphor 13 becomes higher (the value of b becomes larger). The chromaticity of the mixture light when b=0 is equal to the emission chromaticity, of the light-emitting element 100 alone since the single crystal phosphor 13 does not produce fluorescence.

Here, the lower limit of the thickness of the plate-shaped single crystal phosphor 13 is 0.15 mm. The thickness of the single crystal phosphor 13 is set to not less than 0.15 mm from the viewpoint of mechanical strength.

Even if the value of a in the compositional formula of the single crystal phosphor 13 is changed, the chromaticity in the direction of the curved line L2 hardly changes since Lu does not function as an activator. Likewise, even if the emission wavelength of the light-emitting element 100 is changed, the chromaticity in the direction of the curved line L2 hardly changes.

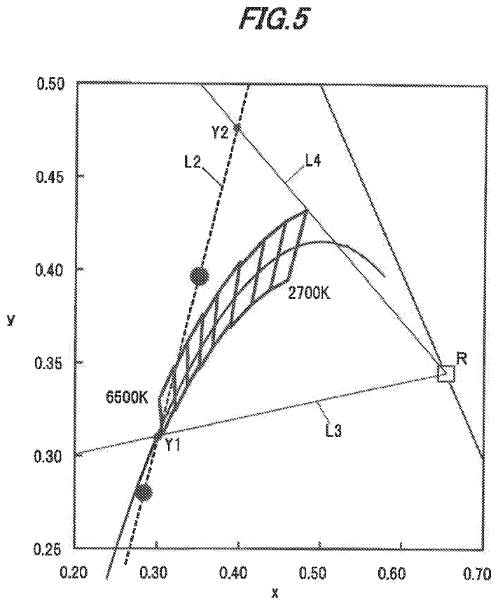

FIG. 5 is a chromaticity diagram which plots the CIE chromaticity of a mixture light yielded by a combination of the light-emitting element 100, the single crystal phosphor 13 and a reddish phosphor.

The curved line L2 in FIG. 5 is equal to the curved line L2 in FIG. 4. The point R indicates a chromaticity (0.654, 0.345) of fluorescence from the reddish phosphor. In addition, eight quadrilateral boxes arranged in a row are chromaticity ranges at color temperatures of 2700 to 6500K defined by the chromaticity standard (ANSI C78.377).

A straight line L3 is a line passing through the point R and the lower edge of the box for the color temperature of 2700K, and a straight line L4 is a line passing through the point R and the upper edge of the box at the color temperature for 6500K. Then, the point Y1 is an intersection of the curved line L2 with the straight line L3, and the point Y2 is an intersection of the curved line L2 with the straight line L4.

Firstly, the Ce concentration and the thickness of the single crystal phosphor are adjusted so that the chromaticity coordinates of the emission light when combining the light-emitting element 100 and the single crystal phosphor 13 are located between the point Y1 and the point Y2 on the straight line L2 in FIG. 5. Next, the amount of the reddish phosphor (the concentration in the sealing material 15 when dispersed in the sealing material 15) is adjusted, thereby producing white light with a color temperature of 2700 to 6500K.

At this time, since the single crystal phosphor 13 and the reddish phosphor absorb fluorescence each other, the relation between the chromaticity R and the combined chromaticity of the light-emitting element 100 and the single crystal phosphor 13 does not linearly vary with respect to the adjusted amount of the reddish phosphor, but the above-mentioned method allows white color roughly at an intended color temperature to be created.

Even if the value of a in the compositional formula of the single crystal phosphor 13 is changed, the chromaticity in the direction of the curved line L2 hardly changes since Lu does not function as an activator. Therefore, when the single crystal phosphor 13 contains Lu, the amount of the reddish phosphor used in combination with the single crystal phosphor 13 and the light-emitting element 100 is adjusted in accordance with the Lu concentration to allow white light with a color temperature of 2700 to 6500K to be created.

In addition, even if the emission wavelength of the light-emitting element 100 or the emission wavelength of the reddish phosphor is changed, the chromaticity in the direction of the curved line L2 hardly changes in the same manner. And, at least when the peak emission wavelength of the light-emitting element 100 is in a range of 430 to 480 nm and the peak emission wavelength of the reddish phosphor is in a range of 600 to 660 nm, adjusting the amount of the reddish phosphor allows white light with a color temperature of 2700 to 6500K to be created in the same manner.

The following simulation was performed to demonstrate that light emitted from the light-emitting device 10 in the second embodiment is excellent in color rendering properties. Here, color rendering properties when the light-emitting device 10 emits light with a color temperature of 3000K will be described as an example.

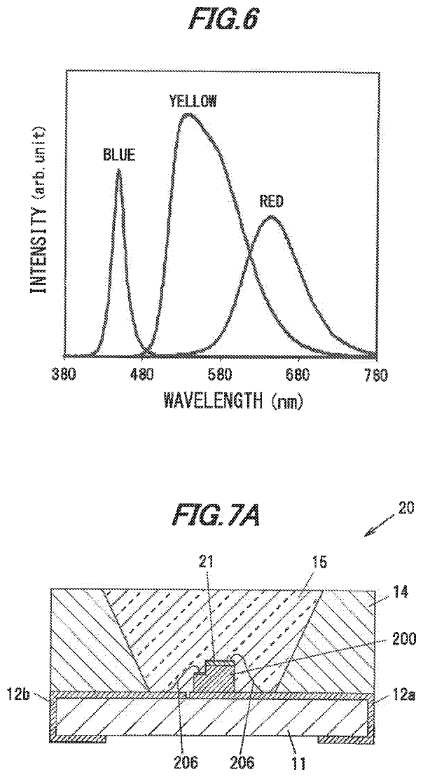

FIG. 6 shows emission spectra of the light-emitting element 100, the single crystal phosphor 13 and the reddish phosphor which were used for simulation (these spectra are referred to as “fundamental spectra”).

The peak wavelengths of fundamental spectra of the light-emitting element 100, the single crystal phosphor 13 and the reddish phosphor are about 450 nm (blue), 535 nm (yellow) and 640 nm (red). The fundamental spectrum of the single crystal phosphor 13 is an emission spectrum of the single crystal phosphor 13 having a composition represented by (Y_{1-a-b}LuₐCe_{b})_{3+c}Al_{5-c}O₁₂ (a=0, b=0.0010, c=0.128).

Firstly, given that the emission spectrum of the light-emitting device 10 can approximate to the synthetic emission spectrum of the light-emitting element 100, the single crystal phosphor 13 and the reddish phosphor, the fundamental spectra of the light-emitting element 100, the single crystal phosphor 13 and the reddish phosphor are fitted to a. spectrum having a chromaticity corresponding to the color temperature of 3000K by the least-squares method, and a linear coupling coefficient of each fundamental spectrum was determined.

Then, an average color rendering index Ra is calculated from the synthetic spectrum obtained by the data fitting. This provides the average color rendering index Ra when the light-emitting device 10 emitting light with a color temperature of 3000K is formed using the light-emitting element 100, the single crystal phosphor 13 and the reddish phosphor of which emission spectra are the fundamental spectra.

Following this, the above-mentioned simulation was repeated while shifting the wavelengths of the fundamental spectra of the light-emitting element 100 and the single crystal phosphor 13 (the fundamental spectrum of the reddish phosphor is fixed) to obtained the average color rendering index Ra at various wavelengths of the light-emitting element 100 and the single crystal phosphor 13. Here, the wavelength of the light-emitting element 100 was varied from the wavelength of the fundamental spectrum in increments of 5 nm in the range of −20 to +30 nm. Meanwhile, the wavelength of the single crystal phosphor 13 was varied from the wavelength of the fundamental spectrum in increments of 5 nm in the range of −45 to +45 nm The results are shown in Table 3 below.

Table 3 shows that a high average color rendering index Ra of not less than 90 or even not less than 95 can be obtained by suitably adjusting the wavelengths of the light-emitting element 100 and the single crystal phosphor 13.

### Third embodiment

The third embodiment is different from the second embodiment in that the light-emitting element is a face-up type LED chip. The explanation for the same features as the first embodiment will be omitted or simplified.

### Configuration of Light-Emitting Device

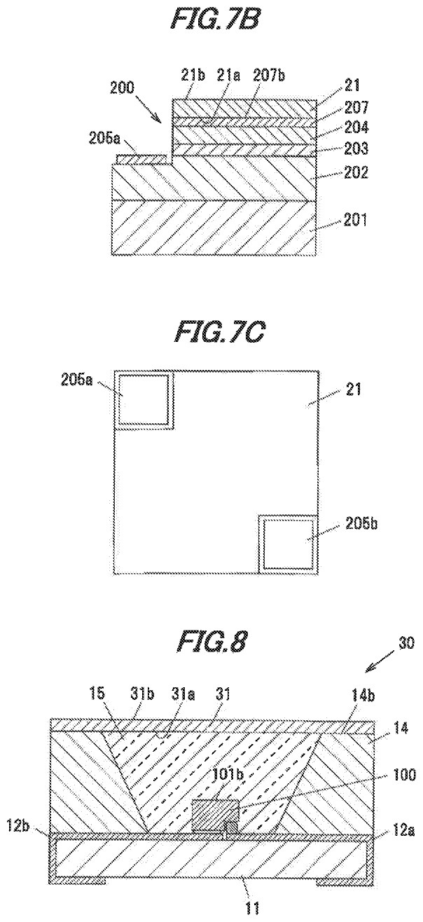

FIG. 7A is a vertical cross-sectional view showing a light-emitting device 20 in the third embodiment. FIG. 7B is an enlarged view showing a light-emitting element 200 and the periphery thereof in the light-emitting device 20. FIG. 7C is a top view showing the light-emitting element 200.

The light-emitting device 20 has the substrate 11 having the wirings 12a and 12b on the surface thereof, the light-emitting element 200 mounted on the substrate 11, a single crystal phosphor 21 provided on the light-emitting element 200, the annular sidewall 14 surrounding the light-emitting element 200, and the sealing material 15 for sealing the light-emitting element 200 and the single crystal phosphor 21.

The light-emitting element 100 is a face-up type LED chip and emits bluish light having an intensity peak at a wavelength of 380 to 490 nm. In the light-emitting element 200, an n-type semiconductor layer 202 formed of, e.g., GaN doped with an n-type impurity, a light-emitting layer 203, a p-type semiconductor layer 204 formed of, e.g., GaN doped with a p-type impurity and a transparent electrode. 207 formed of ITO (indium Tin Oxide), etc., are laminated in this order on an element substrate 201 formed of sapphire, etc. An n-side electrode 205a is formed on the exposed portion of the n-type semiconductor layer 102 and a p-side electrode 205b is formed on an upper surface 207b of the transparent electrode 207.

Carriers are injected from the n-type semiconductor layer 202 and the p-type semiconductor layer 204 into the light-emitting layer 203 which thereby emits bluish light. The light emitted from the light-emitting layer 203 is transmitted through the p-type semiconductor layer 204 and the transparent electrode 207 and exits from the upper surface 207b of the transparent electrode 207. That is, the upper surface 207b of the transparent electrode 207 is a light-emitting surface of the light-emitting element 200.

The substantially square-shaped single crystal phosphor 21 having cutouts at portions corresponding to the installation positions of the n-side electrode 205a and the p-side electrode 205b is arranged on the upper surface 207b of the transparent electrode 207.

The single crystal phosphor 21 is a plate-shaped single crystal phosphor formed of the single crystal phosphor in the first embodiment. The single crystal phosphor 21 is formed of one single crystal and thus does not include grain boundaries.

The single crystal phosphor 21 is placed directly on the upper surface 207b of the transparent electrode 207 without interposition of any members such that a first surface 21a, which is a surface of the single crystal phosphor 21 on the transparent electrode 207 side, is in contact with the upper surface 207b of the transparent electrode 207.

The n-side electrode 205a and the p-side electrode 205b of the light-emitting element 200 are electrically connected respectively to the wirings 12a and 12b via bonding wires 206.

### Operation of Light-emitting device

When power is distributed to the light-emitting element 200, electrons are injected into the light-emitting layer 203 through the wiring 12a, the n-side electrode 205a and the n-type semiconductor layer 202 while holes are injected into the light-emitting layer 203 through the wiring 12b, the p-side electrode 205b, the transparent electrode 207 and the p-type semiconductor layer 204, resulting in that the light-emitting layer 203 emits light. Bluish light emitted from the light-emitting layer 203 is transmitted through the p-type semiconductor layer 204 and the transparent electrode. 207, exits from the upper surface 207b of the transparent electrode 207 and is incident on the first surface 21a of the single crystal phosphor 21.

The single crystal phosphor 21 absorbs a portion of bluish light emitted from the light-emitting element 200 and produces yellowish fluorescence.

A portion of the bluish light emitted from the light-emitting element 200 and travelling toward the single crystal phosphor 21 is absorbed by the single crystal phosphor 21, is wavelength-converted and exits as yellowish light from a second surface 21b of the single crystal phosphor 21. Meanwhile, another portion the bluish light emitted from the light-emitting element 200 and travelling toward the single crystal phosphor 21 exits from the second surface 21b without being absorbed by the single crystal phosphor 21. Since blue and yellow are complementary colors, the light-emitting device 20 emits white light as a mixture of blue light and yellow light.

Meanwhile, in case that the sealing material 15 contains a reddish phosphor, the reddish phosphor absorbs a portion of the bluish light emitted from the light-emitting element 200 and produces reddish fluorescence. In this case, the light-emitting device 20 emits white light as a mixture of blue light, yellow light and red light. Mixing the red light improves color rendering properties of white light.

### Fourth Embodiment

The fourth embodiment is different from the second embodiment in the installation position of the single crystal phosphor. The explanation for the same features as the second embodiment will be omitted or simplified.

FIG. 8 is a vertical cross-sectional view showing a light-emitting device 30 in the fourth embodiment. The light-emitting device 30 has the substrate 11 having the wirings 12a and 12b on the surface thereof, the light-emitting element 100 mounted on the substrate 11, a single crystal phosphor 31 provided above the light-emitting element 100, the annular sidewall 14 surrounding the light-emitting element 100, and the sealing material 15 for sealing the light-emitting element 100 and the single crystal phosphor 21.

The single crystal phosphor 31 is a plate-shaped single crystal phosphor formed of the single crystal phosphor in the first embodiment. The single crystal phosphor 31 is formed. of one single crystal and thus does not include grain boundaries.

The single crystal phosphor 31 is placed on an upper surface 14b of the sidewall 14 so as to close an opening of the annular sidewall 14, The light exiting from the second main surface 101b of the element substrate 101 of the light-emitting element 100 is incident on a first surface 31a of the single crystal phosphor 31.

The single crystal phosphor 31 absorbs a portion of bluish light emitted from the light-emitting element 100 and produces yellowish fluorescence.

A portion of the bluish light emitted from the light-emitting element 100 and travelling toward the single crystal phosphor 31 is absorbed by the single crystal phosphor 31, is wavelength-converted and exits as yellowish light from a second surface 31b of the single crystal phosphor 31. Meanwhile, another portion the bluish light emitted from the light-emitting element 100 and travelling toward the single crystal phosphor 31 exits from the second surface 31b without being absorbed by the single crystal phosphor 31. Since blue and yellow are complementary colors, the light-emitting device 30 emits White light as a mixture of blue light and yellow light.

Meanwhile, in case that the sealing material 15 contains a reddish phosphor, the reddish phosphor absorbs a portion of the bluish light emitted from the light-emitting clement 100 and produces reddish fluorescence. In this case, the light-emitting device 30 emits white light as a mixture of blue light, yellow light and red light. Mixing the red light improves color rendering properties of white light. In case that the light-emitting device 30 does not include the reddish phosphor, the light-emitting device 30 may not have the sealing material 15.

### Fifth Embodiment

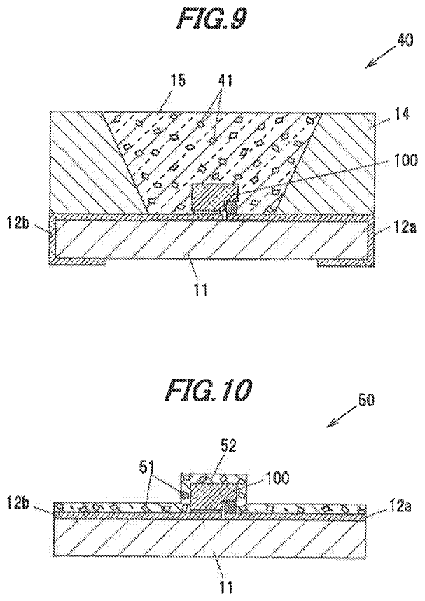

Next, the fifth embodiment of the invention will be described in reference to FIG. 9. FIG. 9 is a vertical cross-sectional view showing a light-emitting device 40 in the fifth embodiment. As shown in FIG. 9, the fifth embodiment is different from the second embodiment in the form and arrangement of the phosphor. Constituent elements of the light-emitting device 40 having the same functions and structures as those in the second embodiment are denoted by the same reference numerals and the explanation thereof will be omitted.

As shown in FIG. 9, the light-emitting device 40 has the light-emitting element 100 such as LED, the substrate 11 supporting the light-emitting element 100, the sidewall 14 formed of a white resin, and the sealing material 15 for sealing the light-emitting element 100.

Particles of a single crystal phosphor 41 are dispersed in the sealing material 15. The phosphor 41 is formed of the single crystal phosphor in the first embodiment and is obtained by, e.g., grinding the single crystal phosphor ingot manufactured in the first embodiment.

The single crystal phosphor 41 dispersed in the sealing material 15 absorbs a portion of bluish light emitted from the light-emitting element 100 and produces yellowish fluorescence having an emission peak at a wavelength of, e.g., 514 to 546 nm. The bluish light, which is not absorbed by the single crystal phosphor 41, is mixed with the yellowish fluorescence produced by the single crystal phosphor 41 and the light-emitting device 49 thereby emits white light.

The single crystal phosphor 41 in the fifth embodiment may be used in the other embodiments. That is, the single crystal phosphor 41 in the fifth embodiment may be used in place of the single crystal phosphor 21 in the third embodiment.

### Sixth Embodiment

Next, the ninth embodiment of the invention will be described in reference to FIG. 10. FIG. 10 is a vertical cross-sectional view showing a light-emitting device 50 in the sixth. embodiment. As shown in FIG. 10, the sixth embodiment is different from the fifth embodiment in the shape of the sealing material which contains particles of the single crystal phosphor. Constituent elements of the light-emitting device 50 having the same functions and structures as those in the fifth embodiment are denoted by the same reference numerals and the explanation thereof will be omitted.

As shown in FIG. 11, the light-emitting device 50 has the light-emitting element 100 such as LED, the substrate 11 supporting the light-emitting element 100, and a sealing material 52 provided to cover the surface of the light-emitting element 100 and the upper surface of the substrate 11.

Particles of a single crystal phosphor 51 are dispersed in the sealing material 52. The single crystal phosphor 51 is formed of the single crystal phosphor in the first embodiment and is obtained by, e.g., grinding the single crystal phosphor ingot manufactured in the first embodiment.

The sealing material 52 is, e.g., a transparent resin such as silicone-based resin or epoxy-based resin, or a transparent inorganic material such as glass. The sealing material 52 in the sixth embodiment is formed not only on the surface of the light-emitting element 100 but also on the substrate 11 in some cases because of the manufacturing process using a coating method, but does not need to be formed on the substrate 11.

The single crystal phosphor 51 dispersed in the sealing material 52 absorbs a portion of bluish light emitted from the light-emitting element 100 and produces yellowish fluorescence having an emission peak at a wavelength of, e.g., 514 to 546 nm. The bluish light, which is not absorbed by the single crystal phosphor 51, is mixed with the yellowish fluorescence produced by the single crystal phosphor 51 and the light-emitting device 50 thereby emits white light.

Although the embodiments of the invention have been described above, the invention is not intended to be limited to the above-mentioned embodiments and the various kinds of modifications can be implemented without departing from the gist of the invention. In addition, the constituent elements in the above-mentioned embodiments can be arbitrarily combined without departing from the gist of the invention.

In addition, the invention according to claims is not to be limited to the above-mentioned embodiments. Further, it should be noted that all combinations of the features described in the embodiments are not necessary to solve the problem of the invention.

In addition, the above-mentioned embodiments are to provide light-emitting devices having high energy efficiency and realizing energy saving, such as LED light-emitting devices, or to provide single crystal phosphors used for such light-emitting devices, hence, an energy-saving effect is obtained.

### Industrial Applicability

The invention provides a YAG-based single crystal phosphor to produce fluorescence in an unconventional color, as well as a phosphor-containing member and a light emitting device including the single crystal phosphor.

### REFERENCE SIGNS LIST

10, 20, 30, 40, 50 LIGHT-EMITTING DEVICE

13, 21, 31, 41, 51 SINGLE CRYSTAL PHOSPHOR

100, 200 LIGHT-EMITTING ELEMENT

What is claimed is:

1. A phosphor-containing member, comprising:
a transparent member; and
particles of a single crystal phosphor dispersed in the transparent member,
wherein the single crystal phosphor has a composition represented by a compositional formula (Y_{1-a-b}LuₐCe_{b})_{3+c}Al_{5-c}O₁₂ (where 0≤a≤0.9994, 0.0002≤b≤0.0067, −0.016≤c≤0.315), and Commission International de l'Eclairage (CIE) chromaticity coordinates x, y of an emission spectrum satisfy a relationship of −0.4377x+0.7384≤y≤−0.4377x+0.7504 when a peak wavelength of excitation light is 450 nm and temperature is 25° C.

2. The phosphor-containing member according to claim 1, wherein the transparent member includes a transparent resin or a transparent inorganic material.

3. The phosphor-containing member according to claim 1, wherein a value of “a” in the compositional formula of the single crystal phosphor is in a range of 0.0222≤a≤0.9994.

4. The phosphor-containing member according to claim 1, wherein the value of “a” in the compositional formula of the single crystal phosphor is 0.

5. A light-emitting device, comprising:
a light-emitting element to emit a bluish light; and
the phosphor containing member according to claim 1.

6. The phosphor-containing member according to claim 2, wherein a value of “a” in the compositional formula of the single crystal phosphor is in a range of 0.0222≤a≤0.9994.

7. The phosphor-containing member according to claim 2, wherein the value of “a” in the compositional formula of the single crystal phosphor is 0.

8. A light-emitting device, comprising:
a light-emitting element to emit a bluish light; and
the phosphor containing member according to claim 2.

9. A light-emitting device, comprising:
a light-emitting element to emit a bluish light; and
the phosphor containing member according to claim 3.

10. A light-emitting device, comprising:
a light-emitting element to emit a bluish light; and
the phosphor containing member according to claim 4.
